(19) United States
(12) Patent Application Publication
(10) Pub. No.: US 2016/0141825 A1
(43) Pub. Date: May 19, 2016

(54) AIR COOLED LASER SYSTEMS USING OSCILLATING HEAT PIPES

(71) Applicant: The Boeing Company, Chicago, IL (US)

(72) Inventors: Wade L. Klennert, Albuquerque, NM (US); Bruce L. Drolen, Altadena, CA (US); Steven E. Fisher, Tijeras, NM (US); Juan M. Ceniceros, Placitas, NM (US)

(73) Assignee: The Boeing Company, Chicago, IL (US)

(21) Appl. No.: 14/547,464

(22) Filed: Nov. 19, 2014

(51) Int. Cl. H01S 3/04; H01S 3/042; H01S 3/0941; H01S 5/024; H01S 3/16

(52) U.S. Cl. CPC H01S 3/0404; H01S 5/02407; H01S 3/1643; H01S 3/0941; H01S 3/042; H01S 5/02453; H01S 3/1611; H01S 3/1608; H01S 3/1675; H01S 3/1616

(57) ABSTRACT

Provided are air cooled laser systems, such as portable air cooled laser systems, and methods of operating thereof. An air cooled laser system includes an oscillating heat pipe having one end thermally coupled to one or more laser diodes and the other end being air cooled. The oscillating heat pipe has an extremely high thermal conductivity (e.g., much higher than that of copper) which allows using ambient air for cooling. This air cooling aspect reduces the size, weight, and complexity of the system. Furthermore, the air cooling aspect reduces power consumption since no power is used for liquid circulation. To enhance air-cooling characteristics, the end of the oscillating heat pipe away from the diodes may be thermally coupled to one or more heat dissipating fins. Furthermore, the system may be equipped with a blower for controlling the flow of air around that end.

### BACKGROUND

Laser systems and, in particular air cooled laser systems, have a wide range of uses, such as fiber optic communications, barcode readers, laser pointers, disk reading and recording, laser printing, scanning, directional lighting sources, and the like. Recent advances in this technology area have greatly expanded the range of these uses and allowed for more advanced and more powerful air cooled laser systems. However, laser diodes generate heat during their operation, i.e., when they emit light. In many cases, more than half of the overall energy supplied to laser diodes is converted into heat. If this heat is not removed in an efficient manner, the laser diodes may overheat causing changes in performance and even permanent damage to the system. For example, if the temperature of a laser diode is not maintained at a predetermined level, the wavelength of light emitted by the laser diode may change as further described below. A traditional approach to heat removal involves circulating a heat transfer fluid between internal and external heat exchangers, which the internal heat exchanger being thermally coupled to the laser diodes. While this approach works well for large stationary laser diodes systems, circulating heat transfer fluids requires many different components, such as pumps, conduits, multiple heat exchangers, which add to complexity and cost and limit applications of air cooled laser systems. At the same time, implementing cooling with ambient air is insufficient for concentrated heat generation associated with laser diodes, especially high power lasers. As such, most portable laser diode systems are currently used only for lower power applications.

### SUMMARY

Provided are air cooled laser systems, such as portable air cooled laser systems, and methods of operating thereof. An air cooled laser system includes an oscillating heat pipe having one end thermally coupled to one or more laser diodes and the other end being air cooled. The oscillating heat pipe has an extremely high thermal conductivity (e.g., much higher than that of copper) which allows using ambient air for cooling. This air cooling aspect reduces the size, weight, and complexity of the system. Furthermore, the air cooling aspect reduces power consumption since no power is used for liquid circulation. To enhance air-cooling characteristics, the end of the oscillating heat pipe away from the diodes may be thermally coupled to one or more heat dissipating fins. Furthermore, the system may be equipped with a blower for controlling the flow of air around that end.

In some embodiments, an air cooled laser system includes an oscillating heat pipe having a first end and a second end opposite of the first end. The first end may be also referred to as a heat adsorbing end or a heating end, while the second end may be referred to as a heat dissipating end or a cooling end. In some embodiments, the oscillating heat pipe has the highest heat transfer coefficient in the direction between the first end and second end. In these embodiments case, the heat is removed from the laser diodes and towards the cooling end in the most efficient manner, which would be different from the systems in which the oscillating heat pipe is used to transfer heat between laser diodes and used to create temperature uniformity rather than rapid heat dissipation that allows for air cooling. In some embodiments, one or more diodes may be mounted between the first end and the second end. In some embodiments, the oscillating heat pipe also has the longest dimension in this direction.

The air cooled laser system also includes a laser diode operable as a light source. The laser diode is disposed on and thermally coupled to the first end of the oscillating heat pipe. The laser diode may be disposed directly over a capillary of the oscillating heat pipe. In some embodiments, the first end of the oscillating heat pipe may be thermally coupled to multiple diodes. Each of these multiple diodes may be disposed over a separate capillary of the oscillating heat pipe.

The air cooled laser system may include one or more heat dissipating fins disposed on and thermally coupled to the second end of the oscillating heat pipe. These fins are air cooled. For example, the fins may be exposed to an air ambient. Furthermore, the air used for air cooling the fins may be previously heated or cooled to control the heat transfer from the fins. The air cooled laser system does not include any water circulating systems, such as pumps, external heat exchangers, and such. The entire heat dissipation occurs from the one or more heat dissipating fins and/or oscillating heat pipe to air. As such, the air cooled laser system may be referred to as an air cooled system. It should be noted that capillaries of the oscillating heat pipe include liquid that assists with the heat transfer from the first end of the pipe to the second end. However, this liquid is not circulated by external means, such as pumps. Some mobility of the liquid within the capillaries is attributed to phase change and other like phenomena further described below.

In some embodiments, the air cooled laser system also includes a blower configured to generate a forced air flow around the one or more heat dissipating fins and/or oscillating heat pipe thereby improving heat dissipating characteristics of the overall system. The air cooled laser system may also include a temperature sensor configured to measure the temperature of the first end of the oscillating heat pipe and/or the temperature of the laser diode. The output of the temperature sensor may be used to control operation of the blower. For example, when the sensed temperature exceeds a certain threshold, the blower may be activated (or the speed of the blower may be increased). As a result of this increased air flow, the heat dissipation from the second end increases and reduces the temperature of the oscillating heat pipe at the second end. This, in turn, increases the heat transfer through the oscillating heat pipe and reduces the temperature at the first end. Furthermore, the output of the temperature sensor may be used to control the current to the laser diode in order to limit the amount of heat generated and, more specifically, to shut down the diodes. This type of control allows operating outside of the conditions for which the cooling portion of the air cooled laser system may be designed to address. For example, if the fins and/or blower are not sufficient for ambient temperature of at least 50° C. when the laser diodes receive the full power, then the current may be lowered when the temperature sensor indicates overheating of the laser diodes at these ambient temperatures thereby lowering the heat generated by the diodes and allowing for the air cooled laser system to continue operating at a reduced power level.

In some embodiments, the air cooled laser system may also include a heater disposed on and thermally coupled to the second end of the oscillating heat pipe. The heater may be used when the ambient environment is cold and the heat transfer through the oscillating heat pipe needs to be decreased. The output of the temperature sensor may be used to control operation of the heater. For example, when the air cooled laser system is operated in the cold ambient, the heat transfer through the oscillating heat pipe may be excessive if the second end (and other components) is exposed to this ambient. As a result, the operating temperature of laser diodes may be below the desirable range and may impact the output of the laser diodes. Heating the second end of the oscillating heat pipe may be used to reduce the heat transfer through the oscillating heat pipe thereby allowing the air cooled laser system to operate at a wide ambient temperature range.

In some embodiments, the one or more heat dissipating fins and the oscillating heat pipe form a monolithic structure. In other words, the one or more heat dissipating fins are not only permanently attached to the oscillating heat pipe but they may also be made from the same block of materials. In more specific embodiments, the one or more heat dissipating fins may be shaped from the oscillating heat pipe and may include capillaries. Alternatively, the one or more heat dissipating fins may be detachably attached to the oscillating heat pipe and can be removed, replaced with other fins, or otherwise altered to change the thermo-coupling between the one or more heat dissipating fins and oscillating heat pipe based on, for example, changed ambient conditions (e.g., temperature, humidity). For example, the contact area between the one or more heat dissipating fins and oscillating heat pipe may be changed by sliding the fins with respect to the pipe, which in turn alters the heat transfer between these two components.

In some embodiments, various laser gain material devices may be used in addition or instead of laser diodes. The laser gain material devices are not electrically pumped. The laser diodes described herein may be used to optically pump the gain materials. The laser gain material devices may be disposed on the oscillating heat pipe in a manner similar to the laser diodes described in this disclosure. Some examples of laser gain materials include Yb:YAG, Nd:YAG, Yb:KYW, doped sesquioxides, tungstates, erbium and thulium doped crystals, doped Ca salts including Yb:CaF2, and doped glass.

The air cooled laser system also includes an additional laser diode. The laser diode, oscillating heat pipe, and additional laser diode may form a stack such that the oscillating heat pipe is disposed between and thermally coupled to the laser diode and additional laser diode. In some embodiments, the additional laser diode is shifted with respect to the laser diode along the first end of the oscillating heat pipe such that the projection of the additional laser diode on the surface of the oscillating heat pipe does not overlap with the projection of the laser diode on the same surface of the oscillating heat pipe. As such, additional heat distribution along the first end is achieved by distributed positioning of multiple laser diodes. In some embodiments, each of the laser diode and the additional laser diode is disposed over a separate one of the capillaries of the oscillating heat pipe. As such heat transfer through a non-capillary portion of the oscillating heat pipe is minimized.

When the laser diode and additional laser diode are disposed on and thermally coupled to the first end of the oscillating heat pipe, the heat transfer coefficient of the oscillating heat pipe in the direction between the laser diode and the additional laser diode may be less than in the direction between the first end and the second end. Specifically, the heat transfer may be the highest in the direction between the first end and the second end, which may be substantially normal to the direction between the laser diode and the additional laser diode. As such, this heat transfer aspect is different from examples that use oscillating heat pipes to transfer heat between different laser diodes and maintaining the uniform temperature among these laser diodes.

In some embodiments, the air cooled laser system also includes an additional oscillating heat pipe. The additional oscillating heat pipe may be a part of the stack such that the additional laser diode is disposed between and thermally coupled to the oscillating heat pipe and the additional oscillating heat pipe. In other words, the same laser diode may dissipate its heat into two (or more) oscillating heat pipes at the same time. This feature allows using particularly powerful laser diodes without risk of overheating.

In some embodiments, the oscillating heat pipe is non-planar. For example, the oscillating heat pipe may be longer than the housing of the air cooled laser system and may be specifically shaped to fit into that housing. The non-planar shape may be used to increase the size of the oscillating heat pipe or, more specifically, the surface area of the oscillating heat pipe to provide more heat dissipation. As noted above, this area, which starts at the second end, may be thermally coupled to the one or more heat dissipating fins. In general, the higher the surface area of the oscillating heat pipe that is not coupled to laser diodes, the higher are the heat dissipation capabilities of this pipe. In some embodiments, the air cooled laser system does not have any heat dissipating fins and the entire heat dissipation to the ambient air occurs from the surface of the oscillating heat pipe.

In some embodiments, the one or more heat dissipating fins may include two sets of fins, each set being disposed on a separate side of the same oscillating heat pipe. In other words, the same oscillating heat pipe may be coupled to one or more heat dissipating fins on each side. Each of these two sides extends between the first end and the second end.

Also provided is a method of operating an air cooled laser system. Various examples of air cooled laser systems are described elsewhere in this document. The method may involve supplying electrical power to a laser diode. The laser diode may be operable as a light source of the diode system. The laser diode is disposed on and thermally coupled to the first end of an oscillating heat pipe. The method may proceed with providing an air flow around one or more heat dissipating fins disposed on and thermally coupled to the second end of the oscillating heat pipe. The second end is opposite of the first end. The oscillating heat pipe may have the highest heat transfer coefficient in the direction between the first end and second end. In some embodiments, the method also involves monitoring a temperature of the laser diode and controlling the air flow around the one or more heat dissipating fins based on the temperature of the laser diode. Controlling the air flow around the one or more heat dissipating fins may involve operating a blower that forces the air around the second end of the oscillating heat pipe or, more specifically, around the one or more heat dissipating fins when such fins are present. In some embodiments, the method involves removing the one or more heat dissipating fins from the second end of the oscillating heat pipe. The method may involve heating the second end of the oscillating heat pipe.

These and other embodiments are described further below with reference to the figures.

### BRIEF DESCRIPTION OF THE DRAWINGS

FIG. 1 is a schematic representation of an air cooled laser system that has oscillating heat pipe that provides air cooling capabilities to the system, in accordance with some embodiments.

FIG. 2 is a schematic representation of another air cooled laser system that has an oscillating heat pipe and heat dissipating fins disposed on both sides of that pipe, in accordance with some embodiments.

FIGS. 3A and 3B are schematic representations of laser diode positions with respect to capillaries of an oscillating heat pipe, in accordance with some embodiments.

FIGS. 4A-4C are schematic representations of multiple laser diode positions on an oscillating heat pipe, in accordance with some embodiments.

FIGS. 5A and 5B are schematic representations of air cooled laser systems having shaped oscillating heat pipes, in accordance with some embodiments

FIG. 6 is a method of operating an air cooled laser system having an air-cooled oscillating heat pipe, in accordance with some embodiments.

### DETAILED DESCRIPTION OF EXAMPLE EMBODIMENTS

In the following description, numerous specific details are set forth in order to provide a thorough understanding of the presented concepts. The presented concepts may be practiced without some or all of these specific details. In other instances, well known process operations have not been described in detail so as to not unnecessarily obscure the described concepts. While some concepts will be described in conjunction with the specific embodiments, it will be understood that these embodiments are not intended to be limiting.

### Introduction

A laser diode is an electrically pumped semiconductor and the like (e.g., an optical pumping semiconductor pumped by another electrically pumped semiconductor). Such a diode includes an active region formed by a p-n junction and disposed between the n- and p-regions. The active region may include quantum wells for providing lower threshold currents. The electric carriers, electrons and holes, are pumped into the active region from the n- and p-regions, respectively, due to the forward electrical bias across the diode. The recombination of the electrons and holes in the active region causes light emission. A by-product of this process is heat generated primarily in the active region. This heat needs to be continuously removed during operation of the laser diode.

Laser diodes typically include a double-hetero structure, where the carriers are confined in order to maximize their chances for recombination and light generation with an ultimate goal of all carriers recombining in the active region and producing light. As such, laser diodes include direct bandgap semiconductors, such as gallium arsenide, indium phosphide, gallium antimonide, and gallium nitride. Based on the above, laser diodes are distinguishable from solid-state lasers. However, in some embodiments, laser diodes may be used as optical pumps for solid state lasers or, more specifically, for laser gain material devices.

Advances in the laser diode technology led to new applications of laser diodes. Furthermore, high power laser diodes are becoming more available. For purposes of this disclosure, a high power air cooled laser system is defined as a system capable of producing at least about 100 W of emitted light from the same module. In some embodiments, this value may be at least 200 W per module or even at least 300 W per module or even at least 500 W per module. These trends create specific needs for sophisticated heat dissipation systems. Laser diodes convert electric energy into light energy at about 10%-50% efficiency. The rest is converted into heat and must be removed to avoid thermal stresses and damage to the laser diodes. Inefficient cooling may also result in poor performance of an air cooled laser system as the temperature of the device core has a direct influence on the output wavelength and band gap. For example, for every temperature change of about 3° C., the wavelength of the laser diode can change nearly 1 nm. Also, the light intensity may decrease with the operating life of the laser diode. Specifically, the heat tends to be very undesirable to laser diodes.

The operating temperature of a laser diode's substrate generally should be less than 90° C. for most applications, which requires significant cooling especially for high power lasers. In conventional air cooled laser systems, laser diodes are soldered to bulky copper heat spreaders. These spreaders are attached to heat exchangers using pipes that carry circulating heat transfer fluid (e.g., water). The heat spreaders help with reducing localized heating of the laser diodes (effective operating as heat spreaders) and to transfer the heat to the fluid (effectively operating as internal heat exchangers). For low power laser diodes, copper heat spreaders having heat dissipating fins may be sufficient, but this approach does not work for higher power systems in which the thermal conductivity of copper is simply not enough. By way of an example, a set of laser diodes may be placed into arrays about 1 centimeter long by 100 micron wide with a 50% fill factor resulting in 200 W of continuous heat generation requiring 200 W of refrigeration, which cannot be achieved with conventional air cooled systems. Even at 100 W, the heat transfer rate required to maintain the diodes at its design temperature requires large amounts of cooling fluid to be run at a room temperature and at a high pressure, which can induce jitter into the laser system. Furthermore, liquid cooled systems require large pumps and heat exchangers that often consume a significant portion of the overall power supplied to the system. Finally, typical copper heat spreaders are heavy and account for the majority of the weight of a typical diode laser system.

Provided are air cooled air cooled laser systems in which laser diodes are disposed on and thermally coupled to oscillating heat pipes operable to dissipate the heat into the ambient air. For example, a laser diode may be directly mounted on an oscillating heat pipe. In comparison to copper, which is used for conventional heat spreaders, the oscillating heat pipe has a much lower thermal resistance. As a result, the temperature control of laser diodes is greatly improved and, in some embodiments, the nominal operating temperature of the laser diode cooling system can be increased from the room temperature (e.g., about 20° C. in conventional systems) to greater than 55° C. in proposed air cooled air cooled laser systems having oscillating heat pipes. This approach greatly reduces the cooling requirements of the overall laser system and allows for direct air cooling. As a result, proposed air cooled laser systems are much lighter than the conventional air cooled laser systems and may be used as portable air cooled laser systems, in some embodiments. Furthermore, significant power consumption (up to 20-40% of the total power) may be realized by increasing the operating temperature and eliminating the water cooling in refrigerated systems.

In some embodiments, a laser diode may be mounted directly above a fluid capillary of an oscillating heat pipe further increasing the heat transfer rate between the diode and the oscillating heat pipe. The heavy copper heat spreader is eliminated and replaced with a much lighter and more efficient oscillating heat pipe. In some embodiments, the thermal conductivity of an oscillating heat pipe is at least about 1 kW/m-K or, more specifically, at least about 5 kW/m-K or even at least about 10 kW/m-K. For comparison, the thermal conductivity of a copper is about 0.3-0.4 kW/m-K. As noted above, the higher thermal conductivity allow the laser diode to operate at higher temperatures and ultimately allow for air cooling even at high ambient temperature, such as greater than 40° C. and even greater than 50° C. (e.g., summer in a desert).

A brief description of oscillating heat pipes is provided below to better understand various aspects of this disclosure. An oscillating heat pipe may be a meandering tube, flat sheet, or any other component having serpentine capillaries. For purposed of this disclosure, the form of an oscillating heat pipe is not limited to a conventional pipe (e.g., a cylinder). Instead, an oscillating heat pipe may have any form suitable for laser diode applications.

During fabrication of an oscillating heat pipe, the capillaries of the pipe may be evacuated and then partially filled with a working fluid. As noted above, the working fluid of the oscillating heat pipe is different from the circulating heat transfer fluid of a conventional fluid cooling system. In the conventional system, the heat transfer fluid is selected such that its boiling point is substantially higher than the operating temperature of the system. On the other hand, the boiling point (at one atmosphere pressure) of the working fluid in an oscillating heat pipe may be selected such that it is comparable with the operating temperature of the laser diode, e.g., between 80° C. and 120° C. or, more specifically, between 90° C. and 100° C. or it might also be chosen to be substantially lower than the operating temperature of the diode in order to allow easy start-up of the operation of the oscillating heat pipe. The surface tension may cause formation of liquid portions and vapor portions within the capillaries. When the heat is applied to the first end of the oscillating heat pipe (e.g., during operation of the laser diode), the working fluid may start to evaporate at this end and may cause an increase in the vapor pressure and an increase in the size of the vapor portions inside the capillaries. The first end may be referred to as an evaporator of the oscillating heat pipe. These increases in the vapor pressure and size of vapor portions push the remaining liquid portions towards the opposite end (e.g., the second end) of the oscillating heat pipe. The second end is air cooled and, in some embodiments, may include one or more heat dissipating fins disposed on and thermally coupled to the second end. The heat dissipating fins are exposed to the ambient air. The second end may be also referred to as a condenser of the of the oscillating heat pipe. As the second end cools by the ambient air, the vapor pressure reduces and condensation of bubbles occurs at that end. This process between the first and second ends is continuous and results in an oscillating motion of the liquid within the pipe. The heat transfer between the two ends of the oscillating heat pipe is due to the latent heat of the vapor and due to the sensible heat transported by the liquid portions as they move within the capillaries. In comparison to a conventional water cooling, the oscillating heat pipe experiences only small pressure drops in the working fluid within the capillaries (even though the capillaries are very small) because the working fluid experiences very little motions and not aggressively circulated within the capillary. Specifically, the working fluid of the oscillating heat pipe does not use external pumps and the oscillating motion of the liquid within the pipe is established due to changes in vapor pressure, phase transition, capillary actions, and such. Specific variations of oscillating heat pipes include but are not limited to closed-loop oscillating heat pipe, closed-loop oscillating heat pipe with a check valve which controls the direction of the flow within capillaries of the pipe, and closed-end oscillating heat pipe.

### Examples of Air Cooled Laser Systems

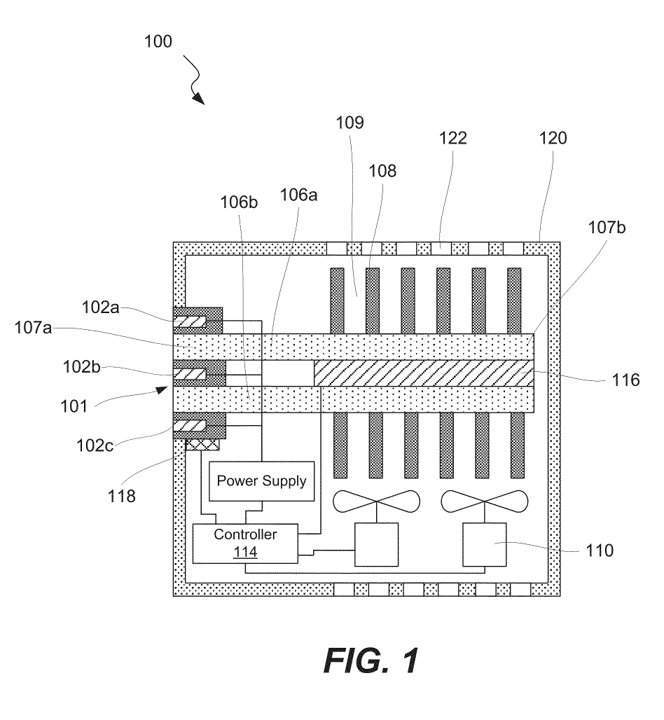

FIG. 1 is a schematic representation of air cooled laser system 100, in accordance with some embodiments. Air cooled laser system 100 includes oscillating heat pipe 106a having first end 107a and second end 107b opposite of first end 107a. Oscillating heat pipe 106a has the highest heat transfer coefficient in the direction between first end 107a and second end 107b. The heat transfer coefficient in other directions (i.e., normal to the direction between first end 107a and second end 107b) may be substantially less (e.g., 10 times less) and often representative of the material forming the body of oscillating heat pipe 106a. For example, oscillating heat pipe 106a may be formed from copper or aluminum and the heat transfer coefficient in the other directions may substantially be the same as the heat transfer coefficients of copper or aluminum, respectively. The comparison of heat transfer coefficients of various solid materials and that of oscillating heat pipes is presented below. The direction between first end 107a and second end 107b may be referred to as a heat transferring direction to reflect that the heat is transferred from first end 107a to second end 107b as further described below. In some embodiments, oscillating heat pipe 106a also has the longest dimension in the heat transferring direction.

Air cooled laser system 100 also includes laser diode 102a operable as a light source. Laser diode 102a is disposed on and thermally coupled to first end 107a of oscillating heat pipe 106a. For purposes of this disclosure, thermally coupling means a connection between two components that facilitates heat transfer between these components. For example, the two components may directly interface each other and have physical contact. In another example, a heat transfer medium (e.g., a thermally conductive adhesive) may be disposed between two components. In general, thermally coupling will be understood by one having ordinary skills in the art.

Laser diode 102a is an electrically pumped semiconductor. Laser diode 102a may include an active region formed by a p-n junction and disposed between the n- and p-regions. The active region may include quantum wells for providing lower threshold currents. Laser diode 102a may include direct bandgap semiconductors, such as gallium arsenide, indium phosphide, gallium antimonide, and gallium nitride. In some embodiments, various laser gain material devices may be used in addition or instead of laser diode 102a. The laser gain material devices are not electrically pumped. Laser diode 102a may be used to optically pump the gain materials. The laser gain material devices may be disposed on oscillating heat pipe 106a in a manner similar to laser diode 102a. In fact, in these embodiments, numeral 102a may represent a combination of a laser diode and a laser gain material. Some examples of laser gain materials include Yb:YAG, Nd:YAG, Yb:KYW, doped sesquioxides, tungstates, erbium and thulium doped crystals, doped Ca salts including Yb:CaF2, and doped glass. In some embodiments, the laser gain material may be cooled using one oscillating heat pipe while a laser diode (used to optically pump the laser gain material) may be cooled using a different oscillating heat pipe. Alternatively, a combination of the laser gain material and laser diode may be cooled using the same oscillating heat pipe.

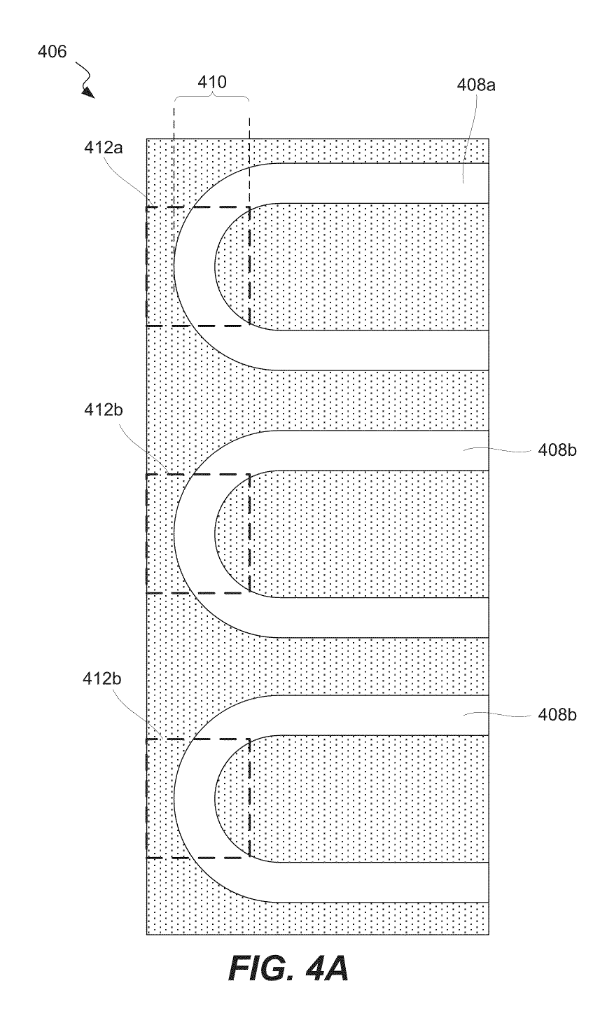

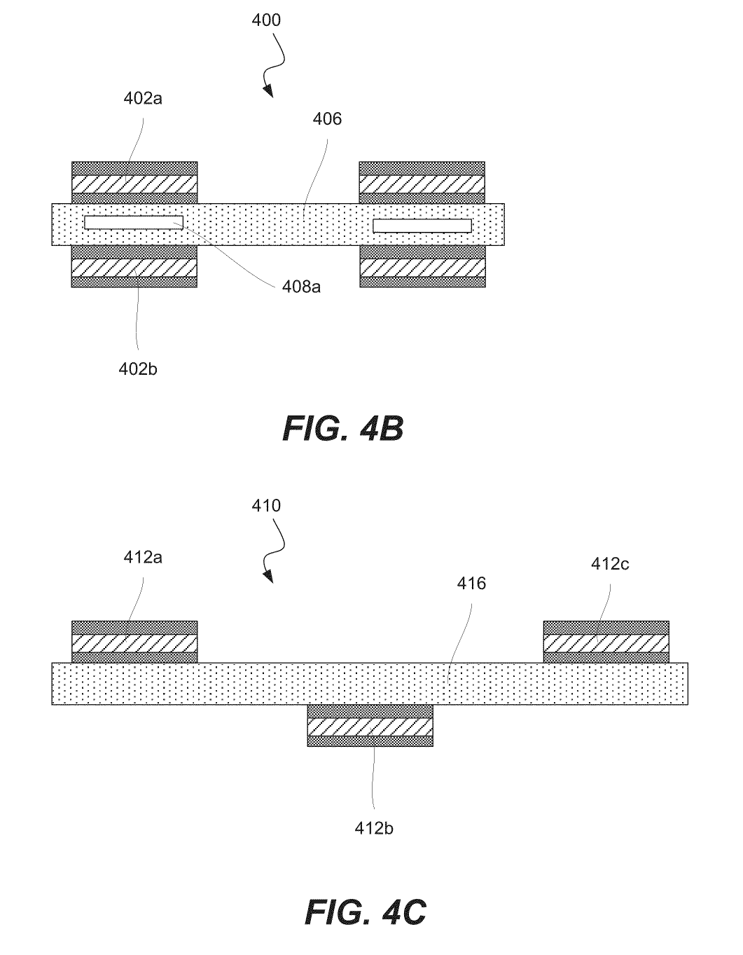

In some embodiments, first end 107a of oscillating heat pipe 106a may be thermally coupled to multiple diodes. For example, FIG. 1 illustrates laser diodes 102a and 102b coupled to different sides of oscillating heat pipe 106a at first end 107a. In this example, oscillating heat pipe 106a is disposed between laser diodes 102a and 102b forming a stack. The stack may include an additional oscillating heat pipe, such as oscillating heat pipe 106b in FIG. 1, and additional laser diodes, such as laser diodes 102c in FIG. 1. Some examples of stacks formed by laser diodes by oscillating heat pipes and laser diodes are also shown in FIGS. 4B and 4C. Specifically, FIG. 4B illustrates assembly 400, in which laser diodes 402a and 402b and oscillating heat pipe 406 form a stack such that laser diode 402a is disposed directly above laser diode 402b. Specifically, projections of laser diodes 402a and 402b on either side of oscillating heat pipe 406 substantially coincide. This stack may be aligned with capillary 408a of oscillating heat pipe 406 to enhance heat transfer through oscillating heat pipe 406. This arrangement of laser diodes 402a and 402b on oscillating heat pipe 406 may be used for example to increase the packing density of laser diodes and may be suitable for less powerful laser diodes. Different assembly 410 is shown in FIG. 4C. In this example, oscillating heat pipe 416 is disposed and thermally coupled between a pair of laser diodes 412a and 412c on one side and laser diode 412b on the other side. However, the positions of laser diodes 412a and 412c on one side is shifted relative to the position of laser diode 412b on the other side. Projections of laser diodes 412a and 412b do not coincide, and projections of laser diodes 412c and 412b do not coincide. In some embodiments, these projections may be equally spaced along the first end of an oscillating heat pipe. This shifting allows more uniform distribution of the heat generation along the first end of oscillating heat pipe 416 and may be more suitable for higher power laser diodes than, for example, an example described above with reference to FIG. 4B.

Returning to FIG. 1, in some embodiments, air cooled laser system 100 also includes one or more heat dissipating fins 108 disposed on and thermally coupled to second end 107b of oscillating heat pipe 106a. One or more heat dissipating fins 108 are exposed to air ambient 109 and are cooled by air ambient 109 during operation of air cooled laser system 100, i.e., when the heat is generated by laser diode 102a on first end 107a of oscillating heat pipe 106a. In other words, during operation of air cooled laser system 100, laser diode 102a produces heat at first end 107a of oscillating heat pipe 106a. The heat is transferred by oscillating heat pipe 106a from first end 107a to second end 107b, where the heat is dissipated into air ambient 109 from second end 107b and/or from one or more heat dissipating fins 108. Because of the extremely high heat transfer coefficient of oscillating heat pipe 106a, the temperature at first end 107a may be within a few degrees of the temperature second end 107b. In some embodiments, the difference in temperature between first end 107a and second end 107b may be less than 10° C. or, more specifically, less than 5° C. or even less than 3° C. When the operating temperature of laser diode 102a is close to 90° C., second end 107b may be sufficiently air cooled at most possible conditions (e.g., ambient air temperature, ambient air humidity) to which a system can be exposed.

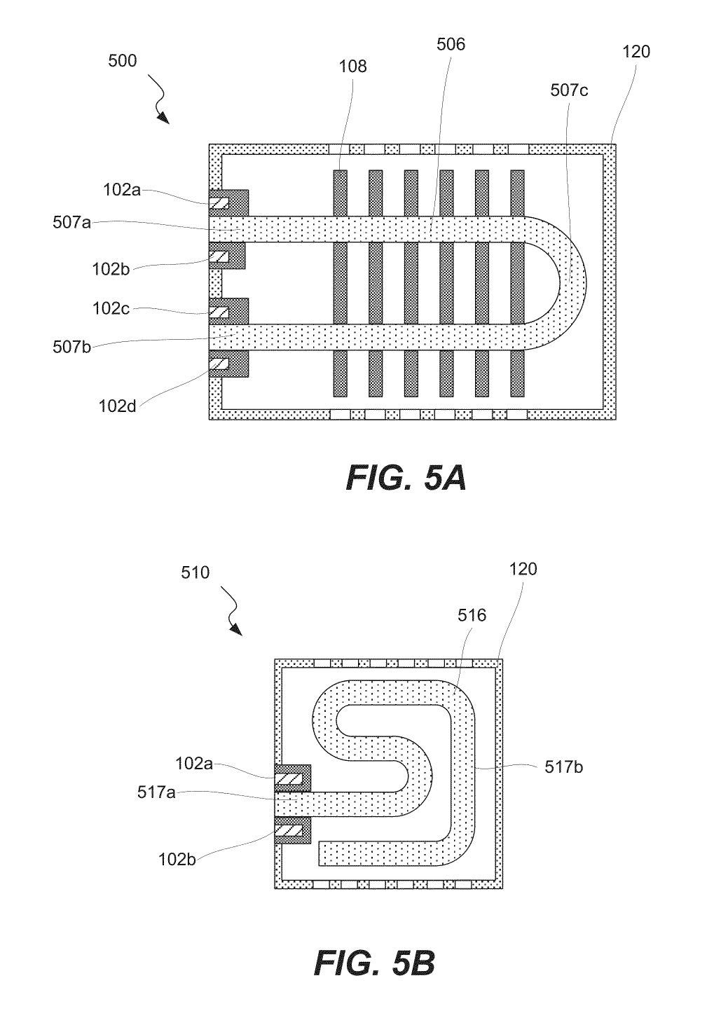

In some embodiments, air cooled laser system 100 does not include heat dissipating fins and all heat is dissipated directly from oscillating heat pipe 106a or, more specifically, from the surface of oscillating heat pipe 106a at second end 107b. Oscillating heat pipe 106a may be specifically shaped to increase its surface area as further described below with reference to FIG. 5B. This approach may be suitable for lower power air cooled laser systems. In some embodiments, air cooled laser system 100 includes heat dissipating fins 108, but heat dissipating fins 108 may not completely cover the surface of oscillating heat pipe 106a at second end 107b and some heat may be dissipated from that surface as well as from heat dissipating fins 108. Alternatively, heat dissipating fins 108 may completely cover the surface of oscillating heat pipe 106a at second end 107b and all heat may be dissipated from heat dissipating fins 108.

In some embodiments, one or more heat dissipating fins 108 and oscillating heat pipe 106a form a monolithic structure. In other words, one or more heat dissipating fins 108 are not only permanently attached to oscillating heat pipe 106a but they may also be made from the same block of materials, e.g., copper, aluminum. Alternatively, one or more heat dissipating fins 108 may be detachably attached to oscillating heat pipe 106a and can be removed, replaced with other fins, or otherwise change the thermo-coupling characteristics between heat dissipating fins 108 and oscillating heat pipe 106a based on, for example, changed ambient conditions (e.g., temperature, humidity).

Heat dissipating fins 108 may be enclosed, while still being accessible to the ambient air. For example, as shown in FIG. 1, air cooled laser system 100 may include enclosure 120 containing most components of air cooled laser system 100 including heat dissipating fins 108. Enclosure 120 may have openings 122 to allow air to flow between air ambient 109 (and around heat dissipating fins 108) and the outside environment (i.e., the environment outside of enclosure 120). In some embodiments, the size of opening 122 may be controlled (e.g., using a slider) based on the outside temperature and/or other parameters thereby controlling the temperature of heat dissipating fins 108 and second end 107b of oscillating heat pipe 106a. For example, when air cooled laser system 100 is operated in a hot environment, opening 122 may be open wider than when air cooled laser system 100 is operated in a cold environment. Air cooled laser system 100 may include a feedback mechanism to indicate to a user about the temperature of laser diode 102a.

In some embodiments, air cooled laser system 100 also includes blower 110 configured to generate an air flow around one or more heat dissipating fins 108 and/or oscillating heat pipe 106a. Blower 110 may have a variable speed and, in some embodiments, may be automatically controlled by controller 114 of air cooled laser system 100. For example, air cooled laser system 100 may also include temperature sensor 118 configured to measure the temperature of first end 107a of oscillating heat pipe 106a and/or the temperature of laser diode 102a. The output of temperature sensor 118 may be used to control operation of blower 110. For example, when the sensed temperature exceeds a certain threshold, blower 110 may be activated (or the speed of blower 110 may be increased) in order to lower the temperature of second end 107b of oscillating heat pipe 106a thereby increasing the heat transfer through oscillating heat pipe 106a and, in turn, decreasing the temperature of first end 107a. Furthermore, forced air may be provided by other systems, such as heating, ventilating, and air conditioning (HVAC) system of a facility (e.g., an aircraft) in which air cooled laser system 100 is used.

In some embodiments, air cooled laser system 100 may include heater 116 disposed on and thermally coupled to second end 107b of oscillating heat pipe 106a. The output of temperature sensor 118 (described above) may be used to control operation of heater 116. For example, when air cooled laser system 100 is operated in the cold ambient, the heat transfer through oscillating heat pipe 106a may be excessive if second end 107b is exposed to this ambient. Heating second end 107b of oscillating heat pipe 106a may be used to reduce the heat transfer through oscillating heat pipe 106a thereby allowing air cooled laser system 100 to operate at a wide ambient temperature range. This feature is particularly suitable for portable air cooled laser systems that can be carried to and operated in various conditions, e.g., in a hot desert at one period of time and a freezing condition at another period of time.

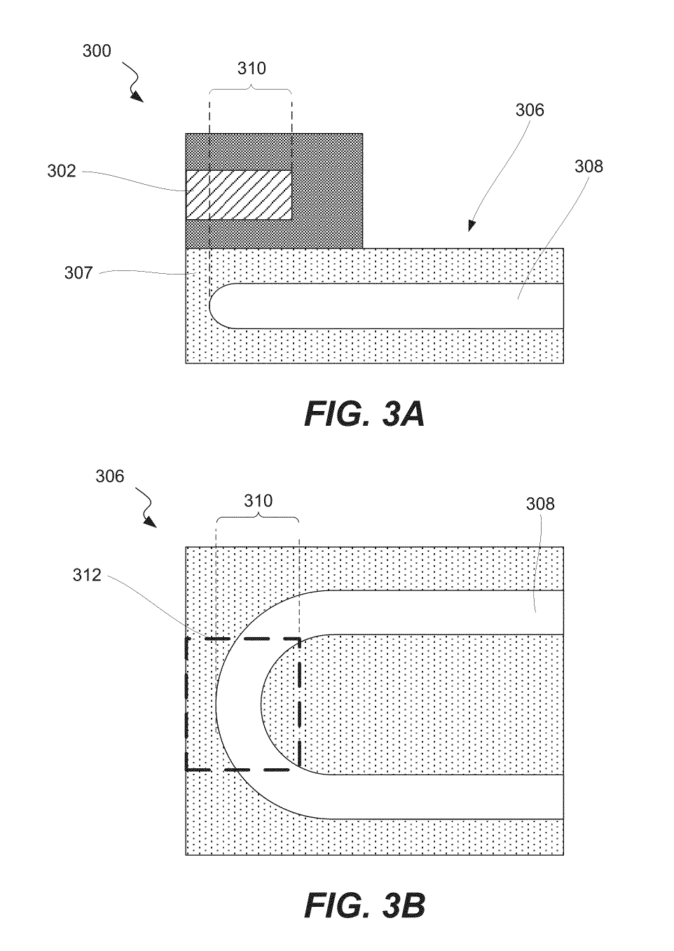

In some embodiments, a laser diode is disposed directly over a capillary of an oscillating heat pipe as, for example, shown in FIGS. 3A and 3B. Specifically, FIG. 3A is a schematic cross-sectional view of partial assembly 300 including laser diode 302 thermally coupled to oscillating heat pipe 306, in accordance with some embodiments. Capillary 308 extends within oscillating heat pipe 306 at first end 307 and forms overlapping zone 310 with laser diode. FIG. 3B is a schematic cross-sectional representation of oscillating heat pipe 306 showing a loop formed by capillary 308. Laser diode projection 312 is shown to illustrate overlapping zone 310. In some embodiments, the center axis of a laser diode is aligned with the center axis of the loop formed by capillary 308 as shown in FIG. 3B. The orientation of laser diode 302 relative to capillary 308 shown in FIGS. 3A and 3B provides efficient heat transfer through oscillating heat pipe 306 as the heat is transferred more directly to the working liquid disposed within capillary 308 in comparison to other examples, when a capillary and laser diode do not overlap and/or are not aligned and the heat transfer has to occur through other portions of the oscillating heat pipe through separate capillary passages. In the latter case, the heat needs to transfer through the material of the oscillating heat pipe that surrounds and forms the capillary. As noted above, the heat transfer coefficient of a solid material is generally much lower than the heat transfer of an oscillating heat pipe caused by phase change and mobility of liquid within the capillaries. As such, more direct heat transfer between the liquid within the capillaries and laser diode results in a more efficient heat transfer.

In some embodiments, air cooled laser system 100 includes one or more additional laser diode, such as laser diodes 102b and 102c in FIG. 1. Two or more laser diodes may form a stack together with an oscillating heat pipe as, for example, shown in FIG. 1 and, more specifically, in FIGS. 4B and 4C. Specifically, FIG. 4B illustrates oscillating heat pipe 406 disposed between and thermally coupled to laser diode 402a and laser diode 402b.

In some embodiments, air cooled laser system 100 also includes one or more additional oscillating heat pipes, such as oscillating heat pipe 106b in FIG. 1B. Two oscillating heat pipes 106a and 106b and laser diode 102b may form a stack such that laser diode is disposed between and thermally coupled to both oscillating heat pipes 106a and 106b.

In some embodiments, an oscillating heat pipe is non-planar. Such an oscillating heat pipe may be also referred to as a shaped oscillating heat pipe. The non-planar shape may be used to increase the size of the oscillating heat pipe or, more specifically, the surface area of the oscillating heat pipe thermally coupled to the one or more heat dissipating fins or being used for direct heat dissipation to ambient air and, therefore, having higher heat dissipation capabilities.

Two examples of such oscillating heat pipes are presented in FIGS. 5A and 5B. Specifically, FIG. 5A is a schematic representation of air cooled laser system 500 having u-shaped shaped oscillating heat pipe 506. In such configuration, oscillating heat pipe 506 has two first ends 507a and 507b and one second end 507c. The ends are differentiated based in their orientation and thermal coupling to laser diodes of system 500. First end 507a is thermally coupled to laser diodes 102a and 102b, while first end 507b is thermally coupled to laser diodes 102c and 102b. Second end 507c is thermally coupled to a set of heat dissipating fins 108. In this configuration, the heat transfer occurs from both first ends 507a and 507b to common second end 507c. It should be noted that first and second ends of oscillating heat pipes do not always correspond to the actual physical ends of these pipes. For purposes of this document, the first end and second end are defined based on the direction of the heat flow and, as such, based on position of heat generating components (e.g., laser diodes) and heat dissipating components (e.g., heat fins). In some embodiments, the second end may be a middle portion of the oscillating heat pipe as, for example, shown in FIG. 5A.

FIG. 5B is a schematic representation of another air cooled laser system 510 having shaped oscillating heat pipe 516. In such configuration, oscillating heat pipe 516 has first end 517a and second end 517b. Referring to the note above, in this example, neither one the physical ends of oscillating heat pipe 516 correspond to the second end. First end 517a is thermally coupled to laser diodes 102a and 102b. In some embodiments, an oscillating heat pipe is longer than the enclosure of the air cooled laser system and may be specifically shaped to fit into that enclosure as, for example, shown in FIG. 5B.

In some embodiments, the air cooled laser system does not have any heat dissipating fins and the entire heat dissipation to the ambient air occurs from the surface of the oscillating heat pipe, as, for example, shown in FIG. 5B.

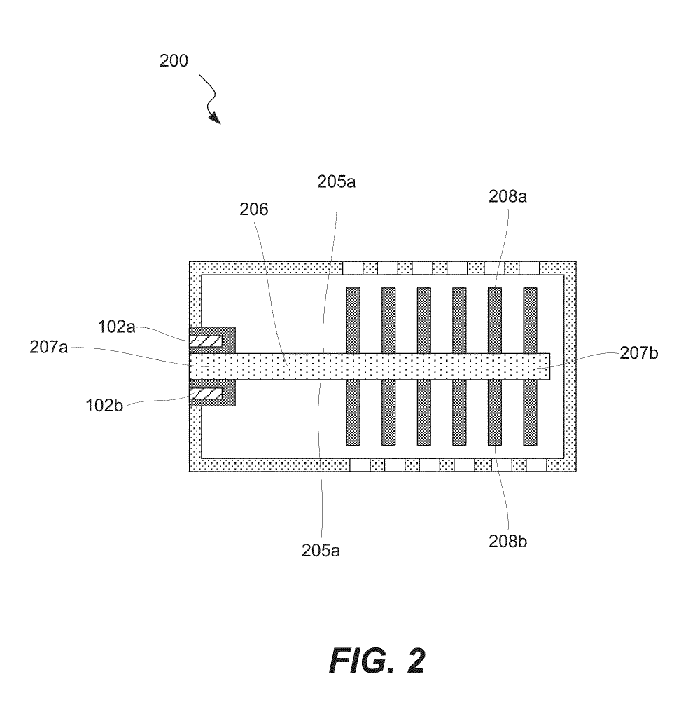

In some embodiments, heat dissipating fins are disposed on two sides of an oscillating heat pipe, as, for example, shown in FIG. 2. Specifically, FIG. 2 illustrates air cooled laser system 200 including oscillating heat pipe 206 having first end 207a and second end 207b. First end 207a is thermally coupled to laser diodes 102a and 102b, while second end 207b is thermally coupled to first set of heat dissipating fins 208a and second set of heat dissipating fins 208b. First set of heat dissipating fins 208a is disposed on first side 205a of oscillating heat pipe 206, while second set of heat dissipating fins 208b is disposed on second side 205b of oscillating heat pipe 206, which is opposite of first side 205a. In some embodiments, the same set of heat dissipating fins may be coupled to two different oscillating heat pipes.

In some embodiments, an air cooled laser system is used for ground platforms or aircraft (e.g., rotorcraft) and may operate with a minimum of 10° C. temperature differential at 55° C. ambient temperature at a laser output of at least about 200 W, such as around 300 W. The blower may be sized to produce air velocities from 0-20 m/s of air across the fins. The oscillating heat pipe may have 0.05-0.2 m² surface area, such as about 0.1 m², in the cooling region at the second end. The cooling fins' surface area may be between about 2-20 times greater than the oscillating heat pipe surface area at the second end. In some embodiments, the cooling fins' surface area may be 0.2-2 m². The blower may turn on when the temperature of the ambient air is above 20° C. The speed of the blower may increase as the temperature of the ambient air increases. When the temperature of the ambient air exceeds 55° C., the current to the diodes may be reduced allowing the diodes to operate up to 65 C ambient at reduced output. At ambient temperatures of less than 20° C., the heater may be tuned on and output may be controlled to maintain a 55° C. operating temperature. Other designs for fixed wing air platforms may utilize larger temperature differentials and lower operating temperatures. This allows using smaller fins and forced air from the exterior of the platform if needed.

### Examples of Operating Air Cooled Laser Systems

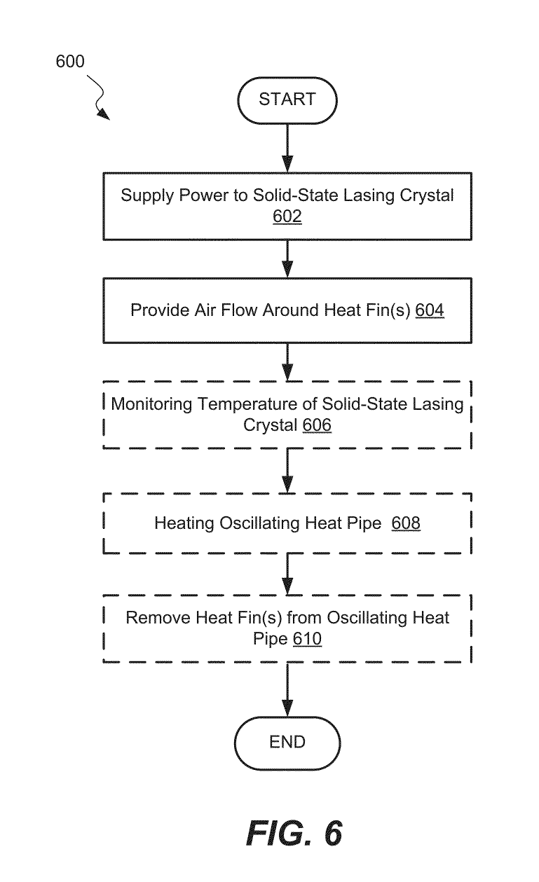

FIG. 6 is a method 600 of operating an air cooled laser system having an air-cooled oscillating heat pipe, in accordance with some embodiments. Various examples of air cooled laser systems are described elsewhere in this document. Method 600 may involve supplying power to the laser diode operable as a light source during operation 602. The laser diode may receive power from a battery of the air cooled laser system or some other power supply. In some embodiments, the supply of the electrical power may be conditioned based on the temperature of the laser diode. As such, if the temperature of the laser diode exceeds a certain threshold (i.e., the diode is overheated), then the power is not supplied.

Method 600 may proceed with providing an air flow around one or more heat dissipating fins disposed on and thermally coupled to the oscillating heat pipe during operation 604. For example, an air blower may be operated to provide forced airflow around the heat dissipating fins. In some embodiments, the airflow may be changed during operation 604 due to various factors, such as ambient temperature, ambient humidity, temperature(s) at one or more locations along the oscillating heat pipe, and the like. Specifically, method 600 may involve monitoring the temperature of a laser diode and controlling the air flow around the one or more heat dissipating fins based on the temperature of the laser diode during optional operation 606. Controlling the air flow around the heat dissipating fins may involve operating the blower. Method 600 may involve heating the second end of the oscillating heat pipe during optional operation 608. In some embodiments, method 600 involves removing the one or more heat dissipating fins from the second end of the oscillating heat pipe during optional operation 610.

### Conclusion

Although the foregoing concepts have been described in some detail for purposes of clarity of understanding, it will be apparent that certain changes and modifications may be practiced within the scope of the appended claims. It should be noted that there are many alternative ways of implementing the processes, systems, and apparatuses. Accordingly, the present embodiments are to be considered as illustrative and not restrictive.

1. An air cooled laser system comprising:
an oscillating heat pipe looping between a first end and a second end opposite of the first end,
wherein the oscillating heat pipe has a highest heat transfer coefficient in a direction between the first end and the second end; and
a laser diode operable as a light source,
wherein the laser diode is disposed on and thermally coupled to the first end of the oscillating heat pipe, and
wherein the second end of the oscillating heat pipe is air cooled.

2. The air cooled laser system of claim 1, further comprising one or more heat dissipating fins disposed on and thermally coupled to the second end of the oscillating heat pipe providing air cooling to the second end of the oscillating heat pipe.

3. The air cooled laser system of claim 2, further comprising a blower configured to generate an air flow around the one or more heat dissipating fins.

4. The air cooled laser system of claim 3, further comprising a temperature sensor configured to measure a temperature of the first end of the oscillating heat pipe or a temperature of the laser diode, wherein output of the temperature sensor is used to control operation of the blower.

5. The air cooled laser system of claim 4, further comprising a heater disposed on and thermally coupled to the second end of the oscillating heat pipe, wherein the output of the temperature sensor is used to control operation of the heater.

6. The air cooled laser system of claim 2, wherein the one or more heat dissipating fins and the oscillating heat pipe form a monolithic structure.

7. The air cooled laser system of claim 2, wherein the oscillating heat pipe is removable from the one or more heat dissipating fins.

8. The air cooled laser system of claim 1, further comprising a laser gain material disposed next to the laser diode for optically pumped by the laser diode, wherein the laser gain material is selected from the group consisting of YAG, Nd:YAG, Yb:KYW, doped sesquioxides, tungstates, erbium and thulium doped crystals, doped Ca salts including Yb:CaF2, and doped glass.

9. The air cooled laser system of claim 1, further comprising an additional laser diode, wherein the laser diode, the oscillating heat pipe, and the additional laser diode form a stack such that the oscillating heat pipe is disposed between and thermally coupled to the laser diode and to the additional laser diode.

10. The air cooled laser system of claim 9, further comprising an additional oscillating heat pipe, wherein the additional oscillating heat pipe is a part of the stack such that the additional laser diode is disposed between and thermally coupled to the oscillating heat pipe and the additional oscillating heat pipe.

11. The air cooled laser system of claim 9, wherein the additional laser diode is shifted with respect the laser diode along the first end of the oscillating heat pipe such that a projection of the additional laser diode on a surface of the oscillating heat pipe does not overlap with a projection of the laser diode on the same surface of the oscillating heat pipe.

12. The air cooled laser system of claim 11, wherein each of the laser diode and the additional laser diode is disposed over a separate one of capillaries of the oscillating heat pipe.

13. The air cooled laser system of claim 1, further comprising an additional laser diode disposed on and thermally coupled to the first end of the oscillating heat pipe, wherein a heat transfer coefficient of the oscillating heat pipe in a direction between the laser diode and the additional laser diode is less than in the direction between the first end and the second end.

14. The air cooled laser system of claim 1, wherein the oscillating heat pipe is non-planar.

15. The air cooled laser system of claim 1, wherein the laser diode is disposed directly over a capillary of the oscillating heat pipe.

16. A method of operating an air cooled laser system, the method comprising:
supplying power to a laser diode operable as a light source,
wherein the laser diode is disposed on and thermally coupled to a first end of an oscillating heat pipe,
wherein the oscillating heat pipe loops between the first end and a second end opposite of the first end; and
providing an air flow around one or more heat dissipating fins disposed on and thermally coupled to the second end of the oscillating heat pipe,
wherein the second end is opposite of the first end, and
wherein the oscillating heat pipe has a highest heat transfer coefficient in a direction between the first end and the second end.

17. The method of claim 16, further comprising monitoring a temperature of the laser diode and controlling the air flow around the one or more heat dissipating fins based on the temperature of the laser diode.

18. The method of claim 16, wherein controlling the air flow around the one or more heat dissipating fins comprises operating a blower.

19. The method of claim 16, further comprising removing the one or more heat dissipating fins from the second end of the oscillating heat pipe.

20. The method of claim 16, further comprising heating the second end of the oscillating heat pipe.
